(19) United States
(12) Patent Application Publication
(10) Pub. No.: US 2024/0378329 A1
(43) Pub. Date: Nov. 14, 2024

(54) POOL MOLD SYSTEM AND METHOD OF ASSEMBLY

(71) Applicant: Jason Carey, Sag Harbor, NY (US)

(72) Inventor: Jason Carey, Sag Harbor, NY (US)

(21) Appl. No.: 18/195,108

(22) Filed: May 9, 2023

(51) Int. Cl. G06F 30/13; E04G 21/14; G06Q 50/08

(52) U.S. Cl. CPC G06F 30/13; E04G 21/14; G06Q 50/08; E04H 4/0056

(57) ABSTRACT

A method for building a custom pool that a user, using an online software platform, selects from a set of predefined pool designs and optionally customizes or designs using a plurality of pool sections from a pool section library. The pool sections are fabricated with an expanded polystyrene foam process, and a kit of the pool sections and joining members are assembled into a kit of components which are delivered to the site where the pool will be built. The pool sections are assembled with the joining members in an excavated void to form a pool shell by inserting a joining member into opposing surfaces of each adjoining pair of pool sections, optionally spraying expanded polystyrene foam around the intersection of the adjoining pool sections to strengthen the bond. Concrete is then sprayed onto the pool shell to form a contiguous pool wall surface.

### TECHNICAL FIELD

This application relates generally to designing and building a custom pool such as an in-ground swimming pool, spa, fish pond and the like; and in particular to fabricating a plurality of pool sections from expanded polystyrene (EPS) foam, joining the fabricated pool sections together with rebar or the like to form a pool shell, and then spraying concrete onto the pool shell to form the completed pool.

### BACKGROUND OF THE INVENTION

Water-containing structures such as in-ground swimming pools may be fabricated in various ways, including but not limited to building a pool shell with steel walls and a sand bottom over which a vinyl liner is secured and then water used to fill in the pool and hold the liner in place against the steel walls. In another type of pool, a large hole is excavated for the pool, gravel is laid out on the floor, rebar reinforcing bars are laid out in desired areas, and GUNITE (or other concrete material) is sprayed against the ground and around the rebar to form the pool. Optionally, tiles and coping may be added after the pool has been formed.

In-ground pools such as those described above suffer from several disadvantages, including notably a lack of insulation sufficient to provide an adequate heat barrier with respect to the ground, resulting in freeze/thaw cycles in cold climates. This results in a requirement to replace the concrete (or vinyl liner) periodically. Another disadvantage in the prior art process is that the homeowner gets little ability to customize the design-they must use what is made available from the manufacturer and/or installer.

### SUMMARY OF THE INVENTION

The present invention addresses these and other shortcomings in the prior art by providing an online platform for designing an in-ground swimming pool or like structure by selecting certain desired pool sections from a plurality of available predetermined pool sections to form the desired size and shape of the pool. A kit of selected pool sections is then delivered to the site where the pool will be constructed, and the pool sections are assembled together to form a pool shell in an excavated void where the pool is desired by using joining members such as rebar or the like. The assembled pool shell is sprayed using concrete or other such finishing material (e.g., GUNITE), and the pool shell is left in place as an insulating barrier with respect to the ground.

As a result of creating the final pool shell from the various pool sections, the concrete is not sprayed against the ground directly. This provides a more stable surface against which the concrete is sprayed and eventually hardens. This also provides an advantageous insulating barrier to greatly reduce heat loss from the pool water into the ground. This will substantially reduce cracking of the concrete surface of the pool since the freeze/thaw cycles typically occurring in colder climates will be vastly reduced or even eliminated.

In particular, provided herein is a method for building a custom pool that has been selected and/or designed by a user. First, the user executes an online software platform to select a pool design from a set of predefined pool designs, the selected pool design comprising a plurality of pool sections selected from a pool section library comprising a corner pool section, a straight pool section, a bench seat pool section, an adjustable slope pool section, a curved entrance pool section, and a stair pool section, and then optionally customize the selected pool design by adding or deleting one or more pool sections from the selected pool design. Or, rather than selecting a pool design from a set of predefined pool designs, the user may execute the online software platform to assemble a pool design using various pool sections selected by the user from a pool section library that includes a corner pool section, a straight pool section, a bench seat pool section, an adjustable slope pool section, a curved entrance pool section, and a stair pool section.

The online software platform analyzes the user's pool design to generate a list of components required to fabricate the pool shell, the list of components including a plurality of pool sections and a plurality of joining members. The required pool sections are then fabricated from the generated list of components, by selecting a required pool section mold for each of the pool sections to be fabricated, and fabricating each pool section, for example by using an expanded polystyrene (EPS) foam manufacturing process (also may be referred to as expandable polystyrene).

The fabricated pool sections and the plurality of joining members are assembled into a kit of components which are then delivered to the site where the pool will be built. A void is excavated into which the pool will be built, and the pool sections are assembled together with the joining members to form a pool shell. This assembly takes place by inserting a joining member, which may for example be rebar, into opposing surfaces of each adjoining pair of pool sections. In the alternative, a plastic (or other material) channel may be inserted into opposing surfaces of each adjoining pair of pool sections and rebar then inserted into the plastic channels. EPS foam may optionally be sprayed around the intersection of the adjoining pool sections to strengthen the bond therebetween.

Further optionally, selected portions of the pool shell may be cut out or otherwise removed to provide at least one conduit channel for installing water conduits and electric conduits. In this case, plumbing may be installed into the water conduits and electric wiring into the electric conduit channels, and plumbing fixtures and electrical fixtures may be likewise installed.

Concrete or the like is then sprayed onto the pool shell to form a contiguous pool wall surface, or optionally a vinyl liner may be placed over the pool shell, thus forming the completed custom pool.

### BRIEF DESCRIPTION OF THE DRAWING

FIG. 1 is a flowchart of the pool design and kit generation process of a preferred embodiment of the invention;

FIG. 2 is a flowchart of the pool assembly from the pool kit generated by the embodiment of FIG. 1.

FIGS. 3-8 illustrate a set of exemplary web pages that are accessed by the user to execute the pool design.

FIG. 9 is a perspective view of a corner pool section.

FIG. 10 is a perspective view of a straight pool section.

FIG. 11 is a perspective view of a bench seat pool section being joined with a straight pool section.

FIG. 12 is a perspective view of a curved entrance pool section being joined with a corner pool section.

FIG. 13 is a perspective view of an adjustable slope pool section being joined with a straight pool section and a corner pool section.

FIG. 14 is a perspective view of a stair pool section being joined with a corner pool section.

FIG. 15 illustrates the joining of a pair of pool sections using joining members such as rebar.

FIG. 16 is a perspective view of a completed pool shell prior to spraying with concrete, also illustrating in one corner the partially sprayed concrete, and also illustrating the internal placement of several joining members.

FIG. 17 illustrates the joining of a pair of pool sections using an alternative joining member such as rebar that is bent and inserted along a top surface.

FIG. 18 illustrates a bench seat pool section being joined with a straight pool section using an alternative joining member such as rebar that is bent and inserted along the surface.

FIG. 19 illustrates an elongated adjustable pool slope section and a riser section joined at one end of a pool shell to form a beach entrance.

### DETAILED DESCRIPTION OF THE INVENTION

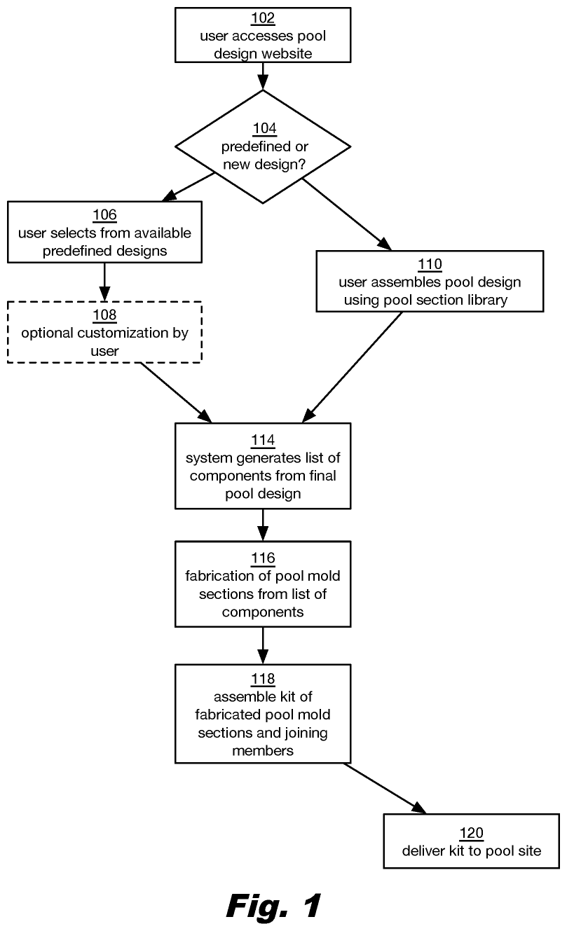

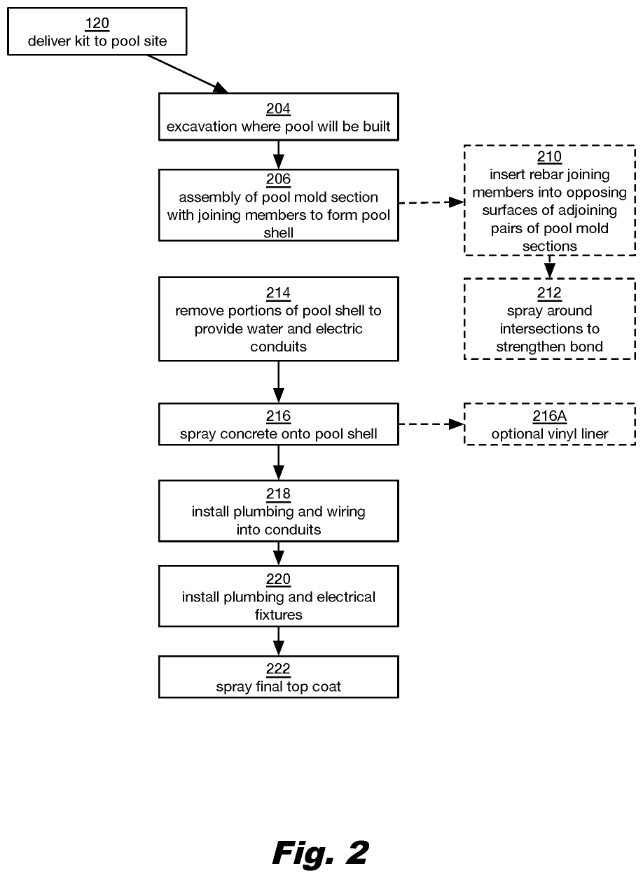

Referring now to the flowcharts of FIGS. 1 and 2, the general process for designing and building a custom pool in accordance with a preferred embodiment of the invention is now described. In FIG. 1, shown is a flowchart of the pool design and kit generation process of a preferred embodiment of the invention. At step 102, the user accesses and executes a software platform that will enable them at step 104 to either (1) select at step 106 a desired pool design from a set of available predefined pool designs, or (2) assemble at step 110 a pool design using a pool section library to select the desired sections of the pool. The software platform may be provided by a server operating on the internet as known in the art, or it may be provided as part of a downloadable package wherein the user installs the software on their computer and executes the design process described herein locally, without requiring use of the internet or other network. In the preferred embodiment described herein, an online internet-based software platform is described, in which internet server-client interactions as known in the art are used to create the pool design for the user.

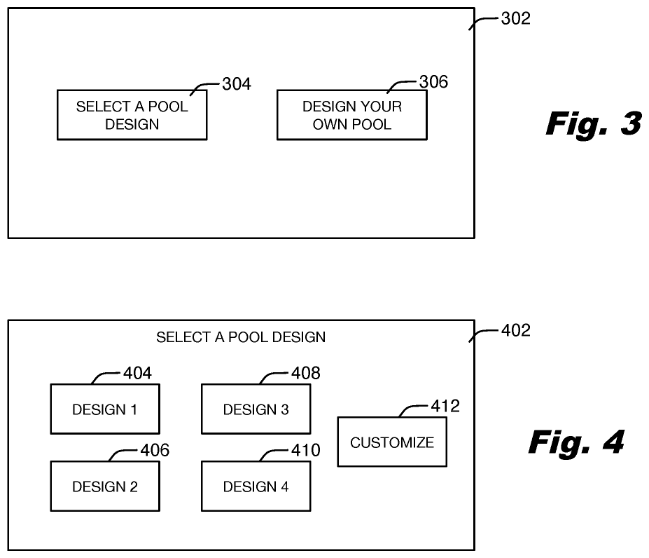

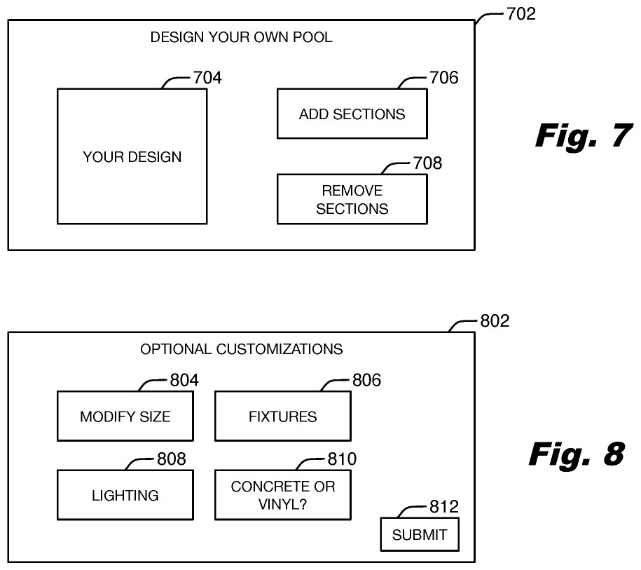

FIGS. 3-8 illustrate a set of exemplary web pages that are provided by the online software platform and accessed by the user to execute the pool design in steps 106, 110. In FIG. 3, an initial landing page 302 for the design website service is shown. Two main options are provided; a button 304 to select a pool design from the available predefined pool designs, and button 306 to design a custom pool. Assuming the user has selected button 304, they will be shown the web page 402 of FIG. 4 to begin the process of selecting a pool design. There, various predefined pool designs are shown, such as a simple rectangle, an L-shaped pool, etc. These are shown illustratively as design 1 button 404, design 2 button 406, design 3 button 408, and design 4 button 410. Fewer or more options may of course be presented to the user, based on the system design. These buttons may integrate illustrations of the available pool designs to help the user in making their selection.

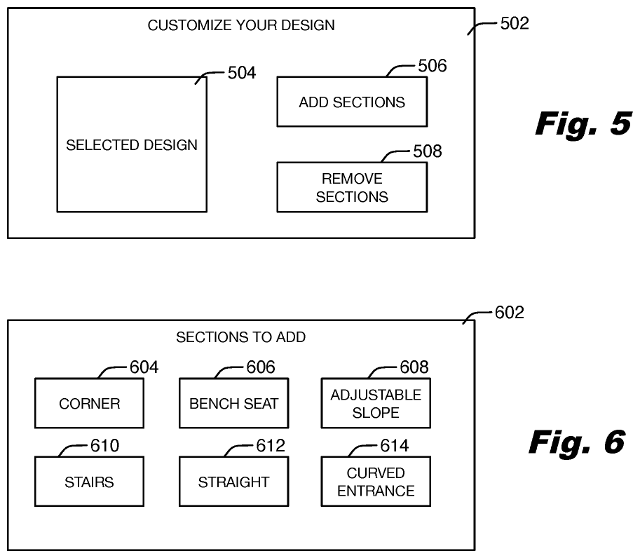

Once the user has selected a desired design, they are given the option of customizing that design by selecting at step 108 the customize button 412. This will cause the web page 502 of FIG. 5 to be displayed. There, the selected design is shown at image 504, and an add section button 506 is provided to allow the user to add other pool sections as desired to the existing design. Also, a remove section button 508 may be provided to allow the user to remove unwanted sections.

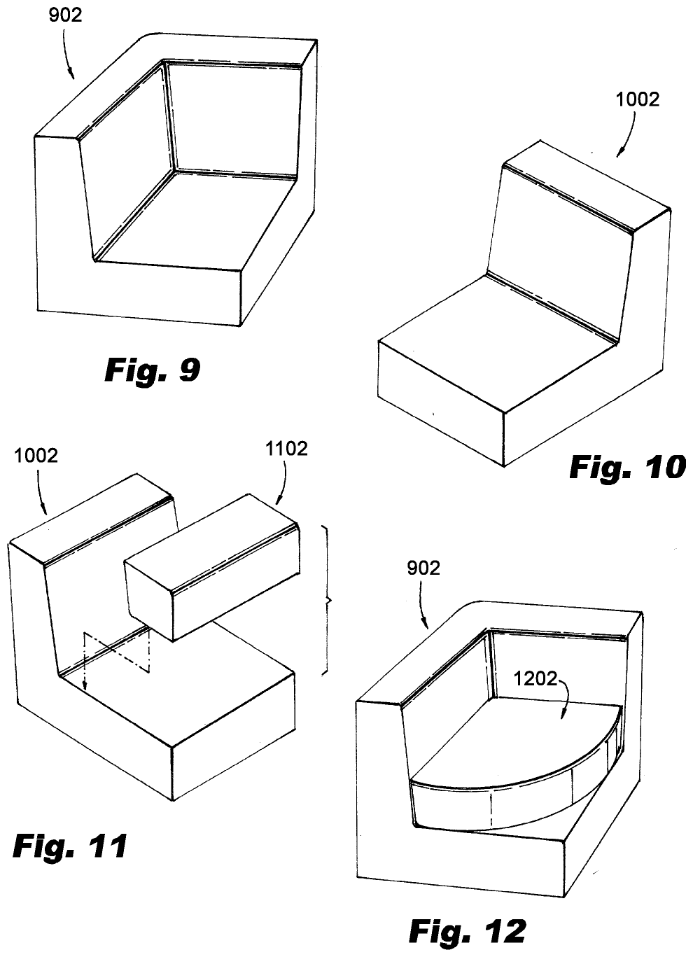

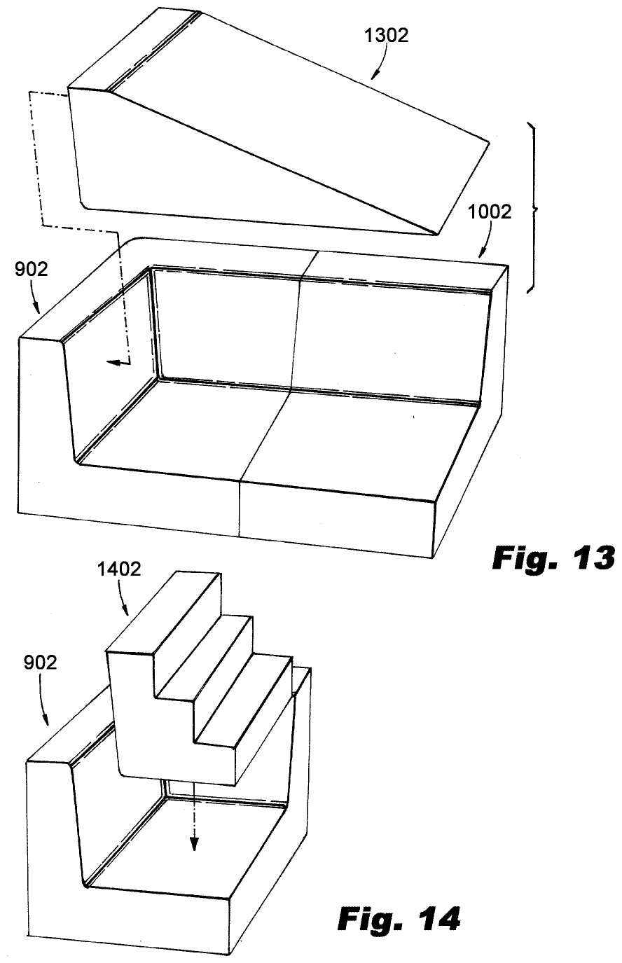

When the add sections button 506 is selected, the web page 602 of FIG. 6 is presented. This page will list all of the available pool sections that may be added to the user's design. For example, the following pool sections may be made available to the user to add to the design:
corner 902 (see FIG. 9) by selecting button 604
bench seat 1102 (see FIG. 11) by selecting button 606
adjustable slope 1302 (see FIG. 13) by selecting button 608
stairs 1402 (see FIG. 14) by selecting button 610
straight section 1002 (see FIG. 10) by selecting button 612
curved entrance 1202 (see FIG. 12) by selecting button 614

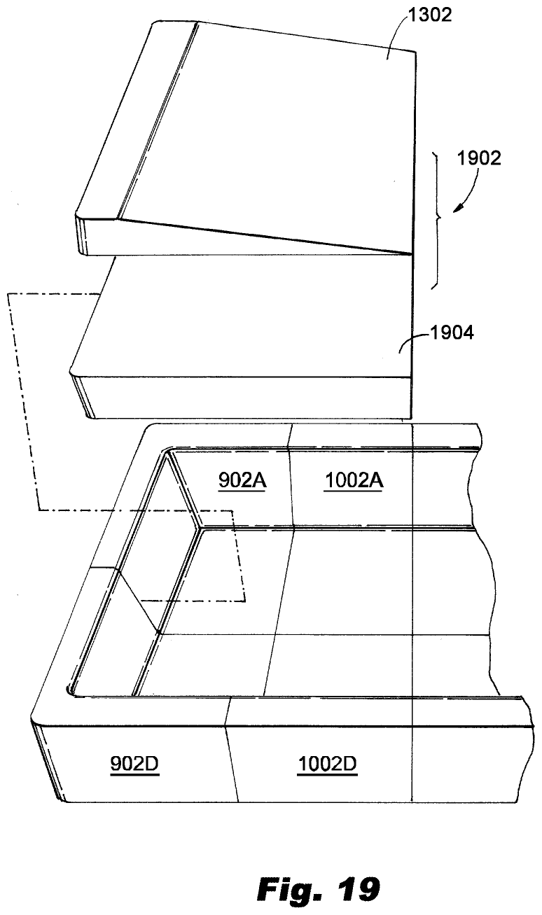

The list above is exemplary; other types of pool sections may also be provided. In addition, various pool section sizes may be provided as part of the options. Thus, a user may start with a plain rectangular pool design and change it, e.g., by adding an adjustable slope (to create a beach entrance section 1902, see FIG. 19), and/or a curved entrance section, etc. In the event that certain pool sections are not compatible with the user's selected design, then that pool section selection may be grayed out to show it is unavailable.

Referring back to FIG. 3, if the user decides to assemble their own custom design from scratch, then they will have selected button 306. In this case, the user will be shown the web selecting the add sections button 706, which will cause the web page 602 to be displayed, as described above. Here, the user will begin the design process by selecting the pool sections they desire, such as corner sections, straight sections, etc. Once selected, the web page 702 is again displayed, and an image 704 will be generated by the software to show them their design. They will then interactively move sections around as they desire, add sections again, and optionally remove unwanted sections via button 708. The design may be displayed in two or three dimensions, it may be rotatable to show different angles and perspectives, etc. as known in the art.

A further customization web page 802 is provided to the user (whether they have selected a predefined design or built one from scratch, both as described above) in FIG. 8. There, the user may modify the size of the pool and/or various pool sections via the button 804. For example, a predefined pool may be a 18′×36′ design; this may be made larger to 20′×40′ if desired. Desired pool fixtures such as a main drain, skimmers, etc., may be selected and/or modified by selection button 806, and various lighting fixtures may be added by selecting the lighting button 808. In addition, the user may select a concrete (e.g., GUNITE) finish, or they may opt for a vinyl liner to be used through button 810. These selections as described above may of course direct the user to additional web pages, not shown herein.

The design process is completely iterative, allowing the user to view it, modify it, etc., as desired. Optionally, the price of each pool section may be displayed, and a running tally of the total price of the pool may be calculated and displayed in real time. Once the user has finalized their design, a submit button 812 may be selected to submit the design for further processing, to be described further below.

Throughout this design process, various web-based techniques (e.g., drop down lists, slide controls, etc.) may be employed by the design platform to enable the user to continue to customize their design, and are not limited by the simple examples provided herein. In addition, both two-dimensional and/or three-dimensional models may be rendered and displayed to the user to help them finalize their design choices. Further optionally, the site where the pool will be built (e.g., the user's yard) may be simulated in the design so they can see how the final design will fit and appear at the desired location.

As mentioned above, the various pool sections that are available in the preferred embodiment are illustrated in FIGS. 9-14 and FIG. 19. FIG. 9 is a perspective view of a corner pool section 902, FIG. 10 is a perspective view of a straight pool section 1002, FIG. 11 is a perspective view of a bench seat pool section 1102 being joined with a straight pool section 1002, FIG. 12 is a perspective view of a curved entrance pool section 1202 being joined with a corner pool section 902, FIG. 13 is a perspective view of an adjustable slope pool section 1302 being joined with a straight pool section 1002 and a corner pool section 902, FIG. 14 is a perspective view of a stair pool section 1402 being joined with a corner pool section 902, and FIG. 19 illustrates an elongated adjustable pool slope section 1302 and a riser section 1904 joined at one end of a pool shell to form a beach entrance 1902.

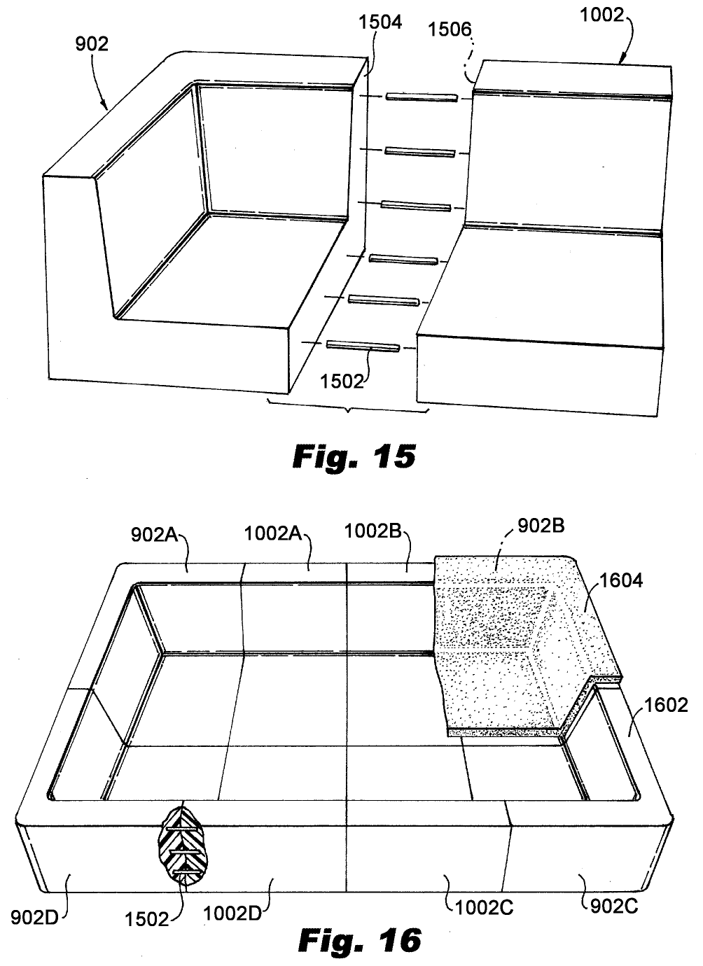

Referring back to the flowchart of FIG. 1, after the design has been finalized and submitted to the system, the online software platform analyzes the user's pool design at step 114 to generate a list of components required to fabricate the pool. The list of components will include the various pool sections required to form the pool, as well as various joining members. For example, a rectangular pool may utilize four corner sections, twelve straight sections, an adjustable slope (for a shallow end), and a set of stairs. The system will determine how many joining members are needed, for example six for each intersection of adjoining sections (see FIG. 15). The joining members 1502 are described further herein. The list of components may optionally include the various plumbing, pool and electrical fixtures selected by the user to complete the design.

Next, the pool sections that are required to design the completed pool are fabricated at step 116 (or optionally taken from an inventory of prefabricated sections), using the list of components generated in step 114. Each pool section will be fabricated by using an appropriate pool section mold that provides the desired shape and size for that pool section. The pool section mold is a custom die that is essentially a negative of the desired pool section, as known in the art. In the preferred embodiment, the pool section is fabricated with expanded polystyrene (EPS) foam, which will provide superior insulating qualities, with relatively low weight and high strength. The use of EPS foam provides several advantages such as being lightweight such that one or two people can lift the fabricated pool section off of the delivery truck and put into place at the job site. The various pool sections are sized to be transported on a delivery truck and easily moved around by the installer without requiring use of a crane or other mechanical device. For example, a corner pool section may be sized at 5 feet 6 inches in each direction, and a straight pool section may also be 5 feet 6 inches in each direction, so they may be carried without a crane.

Thus, a master (negative) pool section mold or die will be created for each different pool section in the system (e.g., a corner, a straight wall, a bench, etc.). The optimum (preferred) thickness of the walls of each resulting pool section is about ten inches, but this may of course vary. This size will generate an optimal R value if about 40, and it is also optimal for holding the concrete that is sprayed against it to form the pool shell as described below.

The various pool sections are made using an EPS fabrication process that is known in the art, and which operates generally as follows. Polystyrene resin granules are impregnated with a blowing agent, such as but limited to pentane gas (C5H12). A small amount of pentane gas is injected into the resin in a process referred to as polymerization.

Next, a pre-expansion process occurs. After the resin granules have been impregnated, they are placed them into a steamer and uses steam to heat the granules. The heat will cause a reaction with the granules and the blowing agent, which will cause the polystyrene granules to expand to approximately fifty times their original size. At this stage there are a large number of individual foam pellets that are ready to be molded.

There are two standard options for molding. The first option is to use a shape molding machine, in which will the foam is molded to the precise size and shape of the pool section being developed, e.g., a corner section. The second option is to use a block molding machine, in which large blocks or sheets of EPS foam are created, which can later be cut to the size and shape of the pool section required.

In either case, the EPS granules are poured into the mold, and a second heating is completed. The second time the granules are heated with steam, they will swell within the mold and become pressed together into one solid piece of foam. It is this mold heating process that transforms them from individual grains to a block of EPS foam.

The EPS pool section is then removed from the mold and allowed to cool to room temperature, which is a function of the size of the pool section. As a final step, the completed pool section is inspected for any cracks or damage before approving it for use.

Further information in this known EPS process may be found, for example, in EXPANDED POLYSTYRENE (EPS) GEOFOAM APPLICATIONS &TECHNICAL DATA, found at https://insulationcorp.com/wp-content/uploads/2012/02/EPS-Geofoam-Applications-Technical-Data-ELECTRONIC-VERSION.pdf

At step 118, the fabricated EPS pool sections and the required joining members are assembled into a kit of components which is then delivered at step 120 to the site where the pool will be built. The joining members may be any type of device that will enable the adjoining pool sections to be held together during assembly of the pool shell at the user's site. In the preferred embodiment, a section of rebar is used as a joining member (see FIG. 15).

Referring now to the flow chart of FIG. 2, a void is excavated at step 204 into which the pool will be built. This may be done at any step of the process and need not wait for the final kit to be delivered. The pool sections are moved from the delivery truck to an area near the excavated void for assembly of the pool shell. At step 206, the pool sections are assembled together with the joining members to form a completed pool shell.

As shown in FIG. 15, this assembly takes place at step 210 by inserting joining members 1502, such as rebar, into opposing surfaces 1504, 1506 of each adjoining pair of pool sections. The corner pool section 902 is shown being joined to the straight section 1002 by inserting the six joining members 1502 into corner pool section surface 1504 and straight pool section surface 1506 and then pushing them towards each other until the adjoining surfaces meet and the joining members are no longer visible (they are completely embedded within the adjoining pool sections 902 and 1002 (see detail in FIG. 16). Although the example shown uses six joining members 1502, more or less may be used as desired.

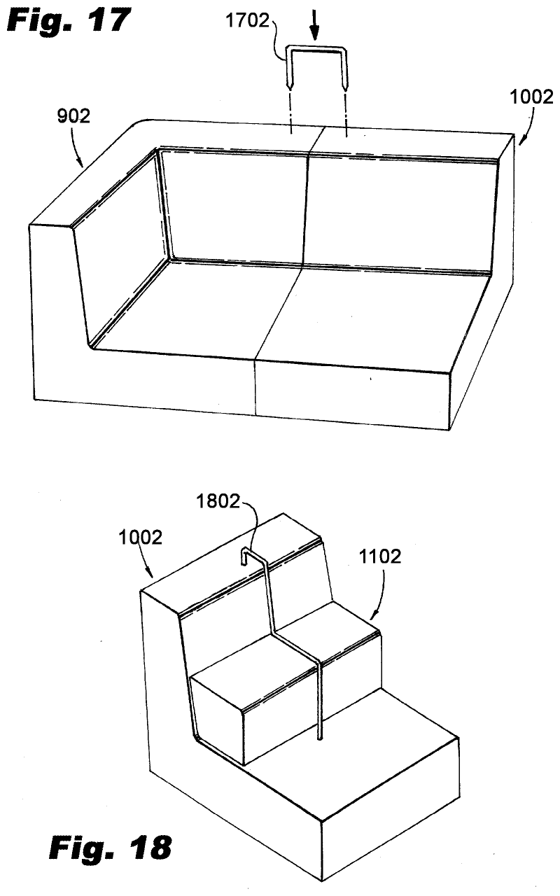

FIG. 17 illustrates the joining of the pair of pool sections 902, 1002 using an alternative joining member 1702 such as rebar that is bent and inserted along the surface. This would provide additional stability to each pair of adjoining pool sections and increased surface area for spraying the concrete. More than one bent joining member 1702 may be used if desired in addition to the straight joining members 1502 in FIG. 15.

FIG. 18 illustrates a bench seat pool section being joined with a straight pool section using an alternative joining member 1802 such as rebar that is bent and inserted along the surface. This would provide additional stability to each pair of adjoining pool sections and increased surface area for spraying the concrete. More than one bent joining member 1802 may be used if desired in addition to the straight joining members 1502 in FIG. 15.

Multiple pool sections may be combined to form desired shapes, such as in FIG. 19 where an elongated adjustable pool slope section 1302 and a riser section 1904 are joined at one end of a pool shell to form a beach entrance 1902.

The rebar joining members 1502 (and 1702, 1802) are able to pierce into the EPS foam material of the pool sections at certain locations indicated on the pool sections, which may be marked during the pool section fabrication process (i.e., they are part of the pool section molds). The rebar could be bent (if needed) on site, or an automatic bending process using e.g., a jig can be used to fabricate the rebar exactly as needed and then delivered with the pool molds to the job site. Heating the rebar may aid in them piercing the EPS pool mold sections during this assembly process.

In the alternative, a channel (e.g., plastic channel) may be inserted into opposing surfaces of each adjoining pair of pool sections and rebar then inserted into the channels. In a further alternative embodiment, the pool sections may be formed with male and mating female portions that insert into each other and interlock accordingly.

At step 212, additional EPS foam may optionally be sprayed or otherwise applied around the intersection of the adjoining pool sections to strengthen the bond between adjoining sections after they are joined by the rebar.

By interconnecting all of the pool sections with each other as set forth in the design, a completed pool shell is formed in the excavated site thereby. See FIG. 16, wherein a rectangular pool shell 1602 is shown. This completed pool shell 1602 has been assembled from four corner pool sections (902A, 902B, 902C and 902D) and four straight pool sections (1002A, 1002B, 1002C, and 1002D). All of these are joined together with joining members 1502 as described and shown with respect to FIG. 15 above.

At step 214, selected portions of the pool shell may be cut out or otherwise removed (e.g., with a circular saw, hot knife or the like) to provide at least one conduit channel for installing water conduits and electric conduits.

Concrete (e.g., GUNITE) or the like is sprayed onto the pool shell to form a contiguous pool wall surface at step 216, thus forming the completed custom pool. This is shown by the partially sprayed concrete 1604 in FIG. 16.

The assembled pool shell holds together to allow the concrete to be sprayed. The pool shell will remain in place, proving an insulating barrier which eliminates the freeze/frost/thaw cycles due to the insulating qualities, and saves a lot of energy. Also, the sprayed concrete lasts longer and is held in place better than in the prior art.

At some point, dirt is used to backfill the space between the completed pool shell and the earth around the shell.

The resulting inside dimensions of the assembled pool shell will be larger than the final desired size of the pool, in order to accommodate for the thickness of the sprayed concrete. For example, if the pool is desired to be 20 feet long, the inside length of the assembled shell will be approximately 21 feet, allowing for 6 inches of concrete to form the pool around the entire shell.

Optionally, a vinyl liner may be placed over the pool shell (rather than spraying concrete) at step 216A. In this embodiment, the EPS foam pool shell becomes the floor and walls of the pool so that the swimmer has a relatively softer surface to walk on than with prior art steel wall/sand bottom pools.

At step 218, plumbing may be installed into the water conduits and electric wiring into the electric conduit channels, and at step 220 plumbing fixtures and electrical fixtures may be likewise installed. This is well known in the prior art; see for example HOW TO ROUTE YOUR POOL'S PLUMBING AND SET UP YOUR EQUIPMENT PAD, found at https://blog.royalswimmingpools.com/how-to-route-your-pools-plumbing-and-set-up-your-equipment-pad.

At step 222, a final top coat may be sprayed onto the concrete walls, thus completing fabrication of the pool.

What is claimed is:

1. A method for assembling a kit of components for building a custom pool at a site comprising:
a user implementing an online software platform to design a pool;
generating, from the user's pool design, a list of components required to fabricate the pool, said list of components comprising a plurality of pool sections and a plurality of joining members;
fabricating the plurality of pool sections from the generated list of components, by executing the steps of:
selecting a required pool section mold for each of the pool sections to be fabricated, and
fabricating each pool section; and
assembling the fabricated pool sections and the plurality of joining members into the kit of components.

2. The method of claim 1 wherein the user implements an online software platform to design a pool by executing the online software platform to select a pool design from a set of predefined pool designs.

3. The method of claim 2 wherein the selected pool design comprises a plurality of pool sections selected from a pool section library comprising a corner pool section, a straight pool section, a bench seat pool section, an adjustable slope pool section, a curved entrance pool section, and a stair pool section.

4. The method of claim 3 further comprising the step of the user customizing the selected pool design by adding or deleting selected pool sections from the selected pool design.

5. The method of claim 1 wherein the user implements an online software platform to design a pool by executing the online software platform to assemble a pool design using a plurality of pool sections selected by the user from a pool section library comprising a corner pool section, a straight pool section, a bench seat pool section, an adjustable slope pool section, a curved entrance pool section, and a stair pool section.

6. The method of claim 1 wherein the step of fabricating each pool section comprises implementing an expanded polystyrene foam process.

7. The method of claim 1 further comprising the step of delivering the kit of components to the site where the pool will be built.

8. The method of claim 7 further comprising the step of excavating, at the site, a void into which the pool will be built.

9. The method of claim 8 further comprising the step of assembling, in the void, the pool sections with the joining members to form a pool shell.

10. The method of claim 9 wherein the step of assembling, in the void, the pool sections with the joining members to form a pool shell comprises inserting a joining member into opposing surfaces of each adjoining pair of pool sections.

11. The method of claim 10 wherein the joining members comprise rebar.

12. The method of claim 9 wherein the step of assembling, in the void, the pool sections with the joining members to form a pool shell comprises inserting a plastic channel into opposing surfaces of each adjoining pair of pool sections and inserting rebar into the plastic channels.

13. The method of claim 9 further comprising the step of spraying expanded polystyrene foam around the intersection of the adjoining pool sections to strengthen the bond therebetween.

14. The method of claim 13 further comprising the step of removing selected portions of the pool shell to provide at least one conduit channel for installing water conduits and electric conduits.

15. The method of claim 14 further comprising the step of spraying concrete onto the pool shell to form a contiguous pool wall surface,

16. The method of claim 14 further comprising the step of placing a vinyl liner over the pool shell.

17. The method of claim 15 further comprising the step of installing plumbing into the water conduits and electric wiring into the electric conduit channels.

18. The method of claim 17 further comprising the step of installing plumbing and electrical fixtures.

19. The method of claim 18 further comprising the step of spraying a final coat on top of the concrete.

20. A method for building a custom pool at a site comprising:
assembling, in a void at the site, a plurality of pool sections with a plurality of joining members to form a pool shell; and
spraying concrete onto the pool shell to form a contiguous pool wall surface.

21. The method of claim 20 wherein the step of assembling, in a void at the site, a plurality of pool sections with a plurality of joining members to form a pool shell comprises inserting a joining member into opposing surfaces of each adjoining pair of pool sections.

22. The method of claim 21 wherein the joining members comprise rebar.

23. The method of claim 20 wherein the step of assembling, in the void, the pool sections with the joining members to form a pool shell comprises inserting a plastic channel into opposing surfaces of each adjoining pair of pool sections and inserting rebar into the plastic channels.

24. The method of claim 20 further comprising the step of spraying expanded polystyrene foam around the intersection of the adjoining pool sections to strengthen the bond therebetween.

25. The method of claim 20 further comprising the step of removing selected portions of the pool shell to provide at least one conduit channel for installing water conduits and electric conduits.

26. The method of claim 25 further comprising the step of installing plumbing into the water conduits and electric wiring into the electric conduit channels.

27. The method of claim 26 further comprising the step of installing plumbing and electrical fixtures.

28. The method of claim 27 further comprising the step of spraying a final coat on top of the concrete.

29. A method for building a custom pool at a site comprising:
implementing an online software platform for a user to design a pool by the steps of
the user executing the online software platform to
select a pool design from a set of predefined pool designs, the selected pool design comprising a plurality of pool sections selected from a pool section library comprising a corner pool section, a straight pool section, a bench seat pool section, an adjustable slope pool section, a curved entrance pool section, and a stair pool section, and
optionally customize the selected pool design by adding or deleting one or more pool sections from the selected pool design, or
the user executing the online software platform to assemble a pool design using a plurality of pool sections selected by the user from a pool section library comprising a corner pool section, a straight pool section, a bench seat pool section, an adjustable slope pool section, a curved entrance pool section, and a stair pool section;
the online software platform analyzing the pool design to generate a list of components required to fabricate the pool, said list of components comprising a plurality of pool sections and a plurality of joining members;
fabricating the plurality of pool sections from the generated list of components, by executing the steps of:
selecting a required pool section mold for each of the pool sections to be fabricated, and
fabricating each pool section by implementing an expanded polystyrene foam process;
assembling the fabricated pool sections and the plurality of joining members into a kit of components;
delivering the kit of components to the site where the pool will be built;
excavating, at the site, a void into which the pool will be built;
assembling, in the void, the pool sections with the joining members to form a pool shell, by the steps of:
inserting a joining member comprising rebar into opposing surfaces of each adjoining pair of pool sections, or
inserting a plastic channel into opposing surfaces of each adjoining pair of pool sections and inserting rebar into the plastic channels, and
spraying expanded polystyrene foam around the intersection of the adjoining pool sections to strengthen the bond therebetween;
removing selected portions of the pool shell to provide at least one conduit channel for installing water conduits and electric conduits;
spraying concrete onto the pool shell to form a contiguous pool wall surface, or optionally placing a vinyl liner over the pool shell;
installing plumbing into the water conduits and electric wiring into the electric conduit channels;
installing plumbing fixtures and electrical fixtures; and
spraying a final coat on top of the concrete.
